(19) United States
(12) Patent Application Publication
(10) Pub. No.: US 2025/0062095 A1
(43) Pub. Date: Feb. 20, 2025

(54) PHOTO-ASSISTED ELECTRON BEAM EMITTER

(71) Applicant: Board of Trustees of Michigan State University, East Lansing, MI (US)

(72) Inventors: Peng ZHANG, Okemos, MI (US); Lan JIN, East Lansing, MI (US); Yang ZHOU, Woodridge, IL (US)

(73) Assignee: Board of Trustees of Michigan State University, East Lansing, MI (US)

(21) Appl. No.: 18/799,382

(22) Filed: Aug. 9, 2024

Related U.S. Application Data
(60) Provisional application No. 63/532,934, filed on Aug. 16, 2023.

(51) Int. Cl. H01J 37/063

(52) U.S. Cl. CPC H01J 37/063; H01J 2237/06341; H01J 2237/0656

(57) ABSTRACT

An electron beam emitter apparatus includes a light source and a radio frequency (“RF”) source. In another aspect, an apparatus includes direct density modulation of photo-assisted field emission from a radio frequency cold cathode. A further aspect provides a radio frequency source connected to an electron emitter or cold cathode having tapered projections, and a photon emitter such as a laser, infrared light or ultraviolet light.

### CROSS-REFERENCE TO RELATED APPLICATIONS

The present application claims priority to U.S. provisional patent application Ser. No. 63/532,934, filed on Aug. 16, 2023, which is incorporated by reference herein.

### GOVERNMENT RIGHTS

This invention was made with government support under contract N00014-20-1-2681 from the Office of Naval Research, contract FA9550-20-1-0409 from the Air Force Office of Scientific Research, contract FA9550-22-1-0523 from the Air Force Office of Scientific Research, and contract DES00022078 from the National Science Foundation-Department of Energy Partnership. The Government has certain rights in the invention.

### BACKGROUND AND SUMMARY

The present application generally pertains to electron beam emitters and more particularly to a photo-assisted electron beam emitter.

Conventional electron beam-based devices have been used in particle accelerators, high-power electromagnetic sources ranging from microwave to X-rays, vacuum electronic devices, e-beam lithography, electron microscopy, space-vehicle neutralization, and emerging vacuum nanodevices. They have also been traditionally employed in telecommunication systems, satellite-based transmitters, radar, communication data links, and electronic countermeasures.

Free-electron beam-based devices utilize the collective interaction of an electron beam with a circuit structure (e.g., either periodic structure or cavity) to convert electron beam energy into electromagnetic radiation. The energy conversion from electron beams into electromagnetic radiation relies on beam modulation. Furthermore, beam modulation is achieved either by controlling the electron emission from the cathode (prebunching) or by passing the electrons through an RF electric field structure that modulates the velocities of the electrons. The former is referred to as density modulation, whereas the latter is known as velocity modulation. It is noteworthy, however, that density modulation and velocity modulation of the beam cannot be separated as they are related by a (linearized) continuity equation; thus, they were used only to distinguish the different ways of initiation of the beam modulation.

At present, traveling wave tubes (“TWTs”) mainly rely on the velocity modulation of the electron beam for power amplification. After the electron velocities are modulated, there is a substantial delay before beam density modulation becomes appreciable, until when the useful gain is produced. Improvements in TWT performance can be enabled by direct density modulation (i.e. prebunching of electron beam) during emission.

In particular, with this initial density modulation, velocity dispersion in the beam is minimized, and the substantial portion of the interaction circuit for the purpose of converting initial velocity modulation into sufficient density modulation is eliminated. This resulted in compact devices with reductions in overall dimensions and weight, through the elimination of a premodulation circuit. Furthermore, initial beam density modulation during emission eliminated a launching loss of an input RF signal, which was a problem in TWTs based on initial velocity modulation. Traditional traveling wave tubes are discussed in Wong, P., Zhang, P. and Luginsland, J., “Recent Theory of Traveling-Wave Tubes: A Tutorial-Review,” Plasma Res. Express, vol. 2, p. 023001(2020). Conventional TWTs often undesirably require high operating voltages and emit stray ions which travel back upstream, striking the emitter tips.

The idea of using direct current modulation of electron beams in microwave amplifiers is well known. Density modulation in amplifiers is also known as Inductive Output Amplifiers (“IOAs”). Historically, density modulation was accomplished with a grid that lays over the surface of a thermionic emitter to control the electron emission. With the advancement of vacuum microelectronics and field emitter arrays (“FEAs”), gate-to-emitter spacing has been reduced to submicron scale, which significantly decreased the electron transit time, thus offering a higher frequency operation. However, there are significant challenges for using such traditional FEAs in high-power tubes, because premature failure due to arcing often occurs at current levels much smaller than the design requirements. This breakdown is a major challenge for FEAs because of the high fields within the structure and a thin-film gate electrode therein. An electrical short between the gate and any individual emitter will burn out the entire FEA and render it unusable. While shields can be added to mitigate the damaging effects of the electrical shorts, a high operating voltage is needed to conventional field emitter arrays to draw sufficient current.

In accordance with the present invention, an electron beam emitter apparatus includes a light source and a radio frequency (“RF”) source. In another aspect, an apparatus includes direct density modulation of photo-assisted field emission from a radio frequency cold cathode. A further aspect provides a radio frequency source connected to an electron emitter or cold cathode having tapered projections, and a photon emitter such as a laser, infrared light or ultraviolet light, which allows for electrical circuit, programmable controller and/or software instructions to cause electrical bias manipulation, frequency manipulation, fast timing control and/or amplification control. A method of using an electron beam emitter or cold cathode, including a light or photon source and a radio frequency source, is also envisioned.

Another aspect includes optical gating providing modulation frequencies (for example, >10 GHz) and timing (for example, fs) of a signal from an electron beam, which is otherwise traditionally limited by the capacitance of the cathode circuit. The shape of the current pulse can be arbitrarily controlled by an electrical circuit, programmable controller and/or software instructions on demand, which is gaussian profile using RF modulation. The combined RF and optical excitation create an emission current that is orders of magnitude higher than using RF alone or optical excitation alone. Therefore, the present apparatus and method enable the development of novel, compact free electron beam based devices, such as accelerators, electron microscopes, electromagnetic radiation sources (RF to x-ray), and the like.

The present photo-assisted field emission current, under the combination of a static bias and an optical field, is significantly larger than either photoemission due to the optical field alone or the traditional field emission due to static field alone. Because of the high nonlinearity of photo- and field-emission, the combined RF bias and optical fields are expected to produce agile current pulse shapes tailored for specific applications. Another advantage of optical gating is that, in the case of emitter arrays, individual emitters can be selectively excited using prescribed optical gating. This selective gating beneficially produces multiple electron beams with separate modulations simultaneously, by various combinations of field emission, photoemission, and even thermionic emission. The present photo-assisted field emission employs greatly reduced RF (or DC) bias to achieve high current compared to the traditional FEAs, which can help reduce or prevent instability induced by poor vacuum conditions when pressed local biased electric field at the emitter tip is close to the field emission threshold.

Furthermore, the occurrence of arcs is diminished in the present apparatus as the relevant heating effect due to photoelectron emission is restrained when the pulses are in a short temporal duration. Thus, the issue of breakdown can be mitigated to provide a more stable and robust emitter operation. Additional features and advantages of the present apparatus and method will become apparent from the following description and appended drawings.

### BRIEF DESCRIPTION OF THE DRAWINGS

FIG. 1 is a diagrammatic sectional view showing the present photo-assisted electron beam emitter apparatus;

FIG. 2 is a diagrammatic view showing the present apparatus;

FIG. 3 is a graph of a quantum model for the present apparatus;

FIG. 4 is a graph showing expected cathode excitation using an RF field and a CW laser field, for the present apparatus;

FIG. 5 is a graph showing expected cathode excitation using an RF field and a pulsed laser field, for the present apparatus;

FIGS. 6A-D are graphs showing expected electron emission current density versus time, under different combinations of RF field strength and laser field strength, for the present apparatus;

FIGS. 7A and B are graphs showing expected electron emission current density versus time, under various laser fields for the present apparatus;

FIGS. 7C and D are graphs showing the expected amplitude spectrum of the emission current density at the RF frequencies of FIGS. 7A and B, respectively, for the present apparatus;

FIG. 8A is a graph showing expected peak emission current as a function of RF field under different laser intensities, for the present apparatus;

FIG. 8B is a graph showing expected FWHM as a function of RF field under different laser intensities, for the present apparatus;

FIG. 8C is a graph showing an expected number of emitted electrons as a function of RF field under different laser intensities, for the present apparatus;

FIGS. 9A-D are graphs showing the expected effect of laser wavelength on electron emission current density, for the present apparatus;

FIGS. 9E-H are graphs showing the expected amplitude spectrum of the emission current density at multiples of RF frequencies corresponding to FIGS. 9A-D, respectively, for the present apparatus;

FIG. 10A is a graph showing expected peak emission current as a function of laser wavelength under various laser intensities, for the present apparatus;

FIG. 10B is a graph showing expected FWHM as a function of laser wavelength under various laser intensities, for the present apparatus;

FIG. 10C is a graph showing an expected number of emitted electrons as a function of laser wavelength under various laser intensities, for the present apparatus;

FIG. 11A is a graph showing expected electron emission current density versus laser pulse time, for the present apparatus;

FIG. 11B is a graph showing the expected amplitude spectrum of the emission current density at multiples of RF frequency corresponding to FIGS. 11A, for the present apparatus;

FIG. 12A is a graph showing expected FWHM of the emission current density as a function of laser wavelength under various laser intensities using a CW laser field, for the present apparatus;

FIGS. 12B-D are graphs showing expected FWHM of the emission current density as a function of laser wavelength under various laser intensities using a pulsed laser field of varying durations, for the present apparatus;

FIG. 13A is a graph showing an expected number density of emitted electrons per RF cycle as a function of laser intensity under different wavelengths using a CW laser field, for the present apparatus;

FIGS. 13B-D are graphs showing an expected number density of emitted electrons per RF cycle as a function of laser intensity under different wavelengths using a pulsed laser field of varying durations, for the present apparatus;

FIG. 14A is a graph showing an expected average current density and a ratio of average over the peak of current density in various RF amplitude and laser field using a CW laser, for the present apparatus; and

FIG. 14B is a graph showing an expected average current density and a ratio of average over the peak of current density in various RF amplitude and laser field using a pulsed laser, for the present apparatus.

### DETAILED DESCRIPTION

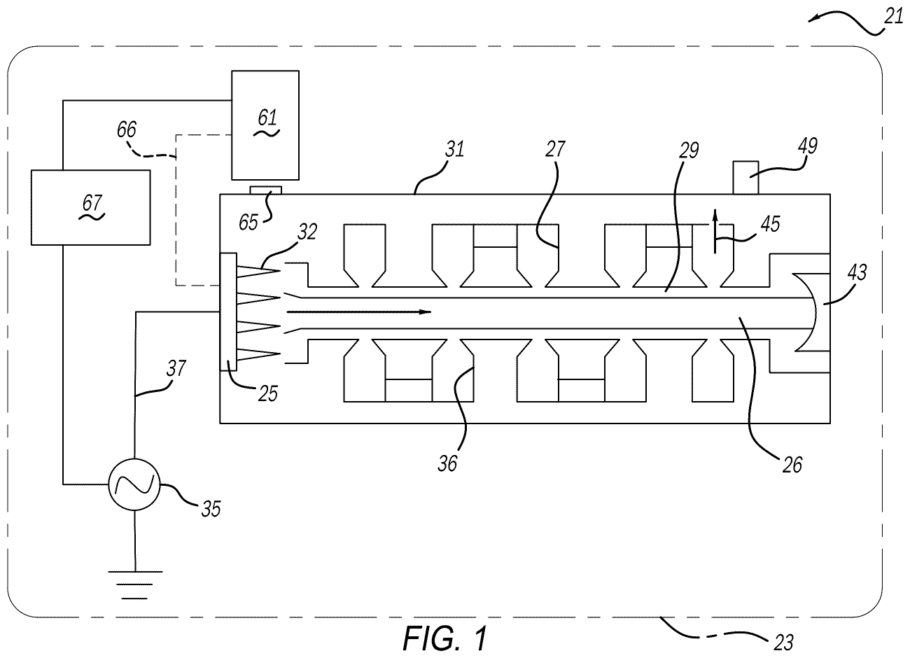

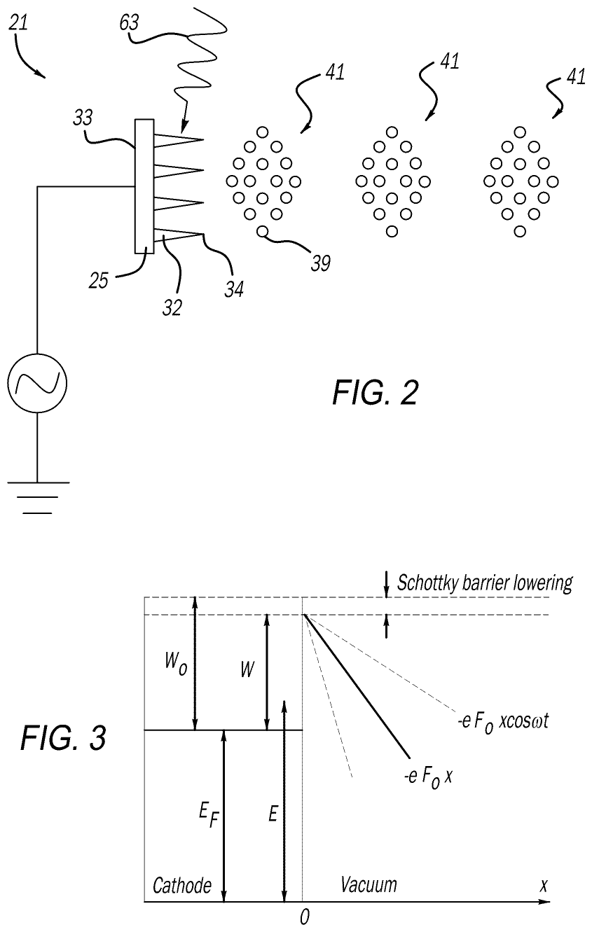

Referring to FIGS. 1 and 2, a preferred embodiment of the present photo-assisted electron beam emitter apparatus 21 includes an outer enclosure, such as an outer space satellite enclosure 23, communications dish amplifier, microwave plasma generator, particle accelerator, coating machine for semiconductors, or the like. In general, a cold cathode 25 type of electron gun emits an electron beam 26 through a coupled cavity circuit 27, or alternately a helix wire conductive circuit (not shown), located within a vacuum chamber 29 inside a longitudinally elongated and metallic, tubular housing 31. The present apparatus and method preferably use a cold cathode type of electron beam emitter, which is powered by a strong voltage but not heated. A cold cathode means that it operates at about room temperature and/or without added heating. Alternately, a heated or hot cathode may be used but is less desirable due to the watered heat energy incurred.

The cold cathode preferably includes multiple longitudinally elongated spikes 32 projecting from a laterally enlarged base 33. Each spike has a frustoconically tapered side wall shape and a distal end diameter of approximately 10 μm-10 nm, and more preferably 10 μm-5 nm. These end tips 34 beneficially control local electrical field enhancement. The quantity of spikes 32 on the cold cathode is preferably 1-1,000, and more preferably an array of 1,000 aligned columns by 1,000 aligned rows of spikes 32.

The electron beam, such as a series of pulses, are emitted into a vacuum between the cathode and a receiver/collector 43. Coupled cavity circuit 27 has multiple, longitudinally spaced apart and depressed wall surfaces 36, which have an annular shape. The wall surfaces confine local electromagnetic field to interact with the electron beam traveling in the hollow center thereof.

A radio frequency (“RF”)/electromagnetic frequency (“EMF”) signal is emitted from an RF source 35 to cathode 25 via an electrical circuit 37, and is then amplified within coupled cavity circuit 27. The electrons in the beam will react to the sinusoidal nature of the electric field when the beam is in the beam-circuit interaction region. The resulting electromagnetic wave extends away from the coupled cavity circuit and acts upon an incoming beam of electrons, such that the initial electrons 39 entering the coupled cavity circuit accelerate in a direction of the beam and, a half cycle thereafter, subsequently entering electrons slow down such that the faster electrons overtake the slower electrons, which creates (if initially unmodulated) or enhances (if initially modulated) electron bunches 41. The electron bunches increase the electric field by inducing greater current in the circuit, thereby amplifying the circuit wave. Furthermore, collector 43 serves to slow down beam 26 in order to recover a majority of the spent beam energy. An input RF communications signal 35 enters the circuit as the cathode bias or as a signal to control laser 63, is amplified through beam-circuit interaction region, and then exits the vacuum chamber via an outlet port 49.

Direct density modulation of high current electron beam emission 26 from RF cold cathode 25 is achieved by using optical excitation. More specifically, a light source, preferably a continuous-wave (“CW”) or pulsed laser 61, is employed to create photo-assisted field emission of periodically bunched electron beams 41. Thus, the bunched electrons are under the combined excitation of an RF field and an optical field. Laser 61 emits light photons 63 through a quartz window 65 in vacuum chamber housing 31. In an alternate configuration, a metallic coated fiber 66 directly connects laser 61 to a backside of cold cathode 25 in order to transmit the photons through the fiber and thereby excite the cathode tips 34, instead of transmitting the photons in an air gap (or outer space vacuum gap) through window 65 and within vacuum chamber 29.

A laser, infrared light or ultraviolet light, which allows for electrical circuit 37, a programmable controller 67 and/or software instructions to cause electrical bias manipulation, frequency manipulation, fast timing control and/or amplification control. The software instructions are stored on nontransient memory, such as RAM or ROM, and run in a microprocessor of controller 67. The software includes instructions configured to automatically: control and/or vary different shapes of the electron beam; control and/or vary duration of the electron beam in response to control of the laser pulse duration; increase electron beam current by controlling and/or varying combined characteristics of the RF field plus laser photons; trigger or actuate the laser after it initiates RF current energization and transmission, when the RF current reaches a certain voltage level or threshold, as measured by an optional sensor connected to the controller; and/or control and/or vary modulation of the electron beam.

In another optional arrangement, the software instructions can automatically or manually cause excitation of all or only some of cold cathode tips 34 with the RF current and/or laser photons, depending on the output desired. For example, all of the tips are RF and photo-excited for continuous and full energy operation. For example, some but less than all of the tips are RF and photo-excited when a nonuniform tailored beam is desired, which induces photo-emission excitation bias, thereby causing increased electron bunch density in the central area of the bunch but with relatively less density at outer areas of the electron bunch. Thus, the controller and software instructions are configured to change and vary characteristics of the electron bunches 41 during use and/or between multiple uses.

For CW photon sources in the UV to optical range (i.e., 200 nm-800 nm), increasing the optical intensity under an RF bias tends to change the current pulse from Gaussian to sinusoidal-like shape, thus offering strong flexibility to control the frequency components in beam current emission. Pulsed photon sources combined with an RF field can produce sharp, high-current electron bunches with pulse duration comparable with or even less than that of the optical pulse. A contour map of the density modulation depth is constructed for different combinations of RF and laser fields, as will be discussed in greater detail hereinafter.

Direct density modulation of a high current electron beam during its emission from an RF cold cathode using optical excitation is achieved with the present apparatus and method by employing pulsed laser-induced (or assisted) electron emission, which offers the possibility of manipulation and control of coherent electron motion in ultrashort spatiotemporal scales. The timing of electron beam emission, and therefore of the electron beam density modulation, can be achieved in femtosecond scale, by laser illuminating DC-biased sharp metallic tips 34. This ultrafast electron emission due to pulsed laser 61, or optical gating, beneficially provides unrivaled precision in phase-control of electromagnetic signals from electron-based devices.

The emission of periodically bunched electron beams under the excitation of an RF field and an optical field, is analyzed using an exact quantum model. A sinusoidal RF electric field (1 GHz) and an optical field (wavelength from 200-1200 nm) are simultaneously applied and emitted to a cold cathode. Electron emission properties, such as peak current density, current pulse width, pulse shape and its corresponding harmonic contents, and electron numbers per RF cycle, are comprehensively analyzed for a wide range of RF field and optical field (i.e., wavelength, laser intensity, and continuous-wave or pulsed form).

FIG. 3 shows a quantum model with a one-dimensional solid-vacuum interface under an RF field F₀ and a laser field F₁ cos ωt, with E_{F} being the Fermi energy of the metal, W₀ being the work function of the cathode, E being the initial energy, W being the effective work function considering the Schottky effect. Electron emission is from an RF cold cathode under an RF field F₀ and an optical field F₁ cos ωt, where F₁ and ω are the optical field strength and its angular frequency, respectively. The RF field is F₀=A cos ω₀t, with A and ω₀ being the amplitude and angular frequency of the RF field, respectively. For RF fields of GHz frequency, it has a period (˜ns) that is orders of magnitude longer than that of the optical field, e.g., 0.67-4 fs for wavelengths in the range of 200 to 1200 nm (UV to NIR). Therefore, the RF field can be regarded as a constant static field in one or multiple laser cycles. Consequently, the photo-assisted field emission induced by the combination of RF and optical fields is modeled using a quantum model by solving the one-dimensional (“1D”) time-dependent Schrödinger equation (“TDSE”) exactly, which is applicable for the arbitrary static electric field, emitter properties (i.e., Fermi energy, work function, and with or without dielectric coatings), and optical field (i.e., wavelength and strength). The quantum model has been extended to various scenarios, such as two-color laser-induced photoemission, few-cycle pulsed laser-induced photoemission, electron emission from dielectric-coated metal surfaces, and electron emission in the nanogaps.

To model the time-dependent oscillating surface barrier (FIG. 3), for simplicity, both the RF field and optical field are assumed to be perpendicular to the cathode surface and cut off at the cathode-vacuum interface. The Schottky barrier lowering 2\sqrt{e³F₀/16πε₀} due to the image charge effect is included, where e is the (positive) elementary charge and ε₀ is the permittivity in free space. It should be noted that this analytical model uses a triangular barrier only, where barrier correction factors and the effect of possible changing barrier height due to oscillating optical field are not considered. Based on the exact solution of TDSE subject to the oscillatory surface barrier due to the RF static and laser fields, the time-averaged electron transmission probability is obtained from the energy level of,

$$D ( ε ) = {\sum }_{n = - ∞}^{∞} {w}_{n} ( ε ) , \qquad ( 1 )$$

where wₙ(ε) denotes the electron transmission probability through the n-photon process, with n<0 representing multiphoton emission process, n=0 direct tunneling process, and n>0 multiphoton absorption process.

Thus, the total emission current density J in a laser cycle can be calculated by

$$J = e {\int }_{0}^{∞} D ( ε ) N ( ε ) d ε , \qquad ( 2 )$$

$$where N ( ε ) = \frac{{mk}_{B} T}{2 {π}^{2} {ℏ}^{3}} ln [ 1 + exp ( \frac{{E}_{F} - ε}{{k}_{B} T} ) ]$$

is the supply function derived from the free electron model for metal, with E_{F}, k_{B}, and T being the Fermi level, the Boltzmann constant, and the temperature, respectively, and N(ε)dε gives the flux of electrons inside the metal imping normal on the metal surface with initial energy between E and ε+dε.

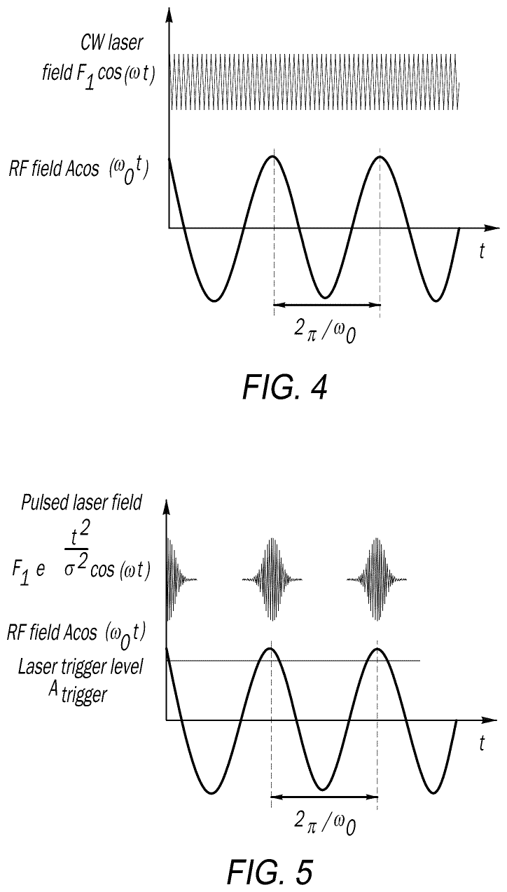

To explore the flexibility of density-modulated electron beam emission, the combination of RF fields with either CW or pulsed photon/laser sources is next considered, as is illustrated in FIGS. 4 and 5. The latter is motivated by the fs scale of the timing of the photoelectron emission under pulsed laser illumination. Cathode excitation using an RF field and a CW laser field can be observed in FIG. 4, and an RF field and a pulsed laser field as is represented in FIG. 5. The laser pulse is triggered by an RF field at a certain voltage level.

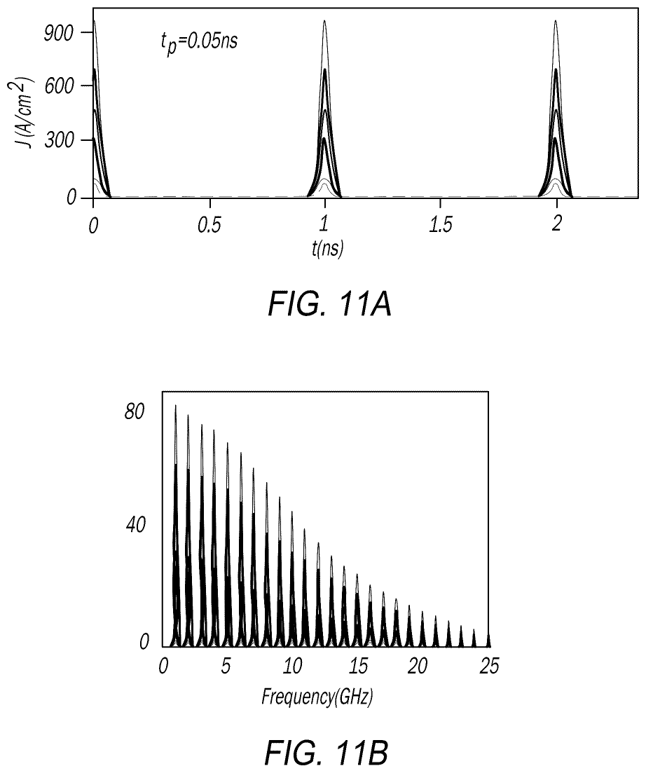

Furthermore, high-frequency beam modulation with precise bunch profiles may be easily realized by the optically gated emitters. It is desirable to produce a train of tightly bunched electrons at a repetition rate of the microwave frequency, in order to achieve synchronism between the electron bunch and the microwave for effective interaction. One approach is to use the RF signal A cos ω₀t to trigger the laser at a certain predetermined level A_{trigger}, so that high-current electron emission occurs only when the laser is triggered (See FIGS. 5, 11A and 11B below). The electron bunch length can be controlled by tuning the trigger level voltage A_{trigger}. Because of the finite rise and fall time of the laser pulse, instead of a constant amplitude of F₁ for the CW laser, the amplitude of the pulse laser is modeled as F₁e^{-t}^{²}^{/Υ}^{²}, where F₁ is the peak of the optical field, and

$$σ = \frac{{τ}_{p}}{2 \sqrt{ln 2}} ≅ \frac{{τ}_{p}}{1.665} ,$$

with τₚ being the FWHM of the optical pulse length. It is assumed that the laser pulse length is much longer than the laser period (i.e. more than 10 laser cycles) so that the laser amplitude F₁e^{-t}^{²}^{/σ}^{²} can be seen as a constant within a laser cycle, so that Eqs. (1) and (2) can still be applied to calculate the emission current density.

It should be noted that the field magnitudes A and F₁ used here are the local field strength at the cathode surface, which may be significantly larger than the input RF and/or optical fields if one considers the large local field enhancement near the sharp emitter tips. The external input fields needed to yield the presented current density level would be lowered according to their corresponding field enhancement factors, i.e., F_{input-RF}=A/β_{static} and F_{input-optical}=F₁/β_{optical}, where the local field enhancement factors for RF field β_{static} and optical field β_{optical} are typically on the order of 10⁴-10⁵ and 10, respectively. As the frequency of the field increases from DC/RF to optical range, the skin depth increases and can become comparable to or even larger than the physical size of the tip, thus, the electric field can penetrate inside the material and the screening effect of free electrons inside the emitter becomes less effective, yielding to a significantly reduced field enhancement factor for optical field as compared to DC/RF field. Techniques such as surface coating, designing tip geometry with plasmonic resonance enhancement, and resonant tunneling can further increase the local field enhancement and reduce the input RF and optical field strengths.

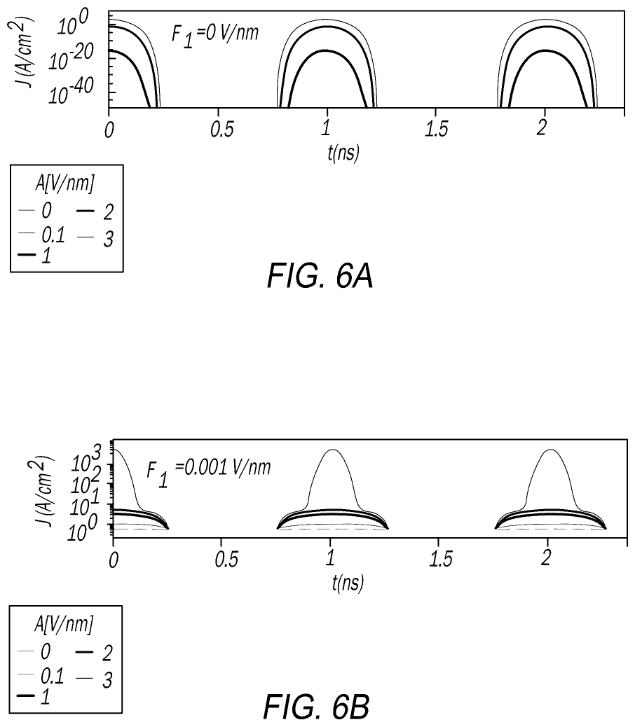

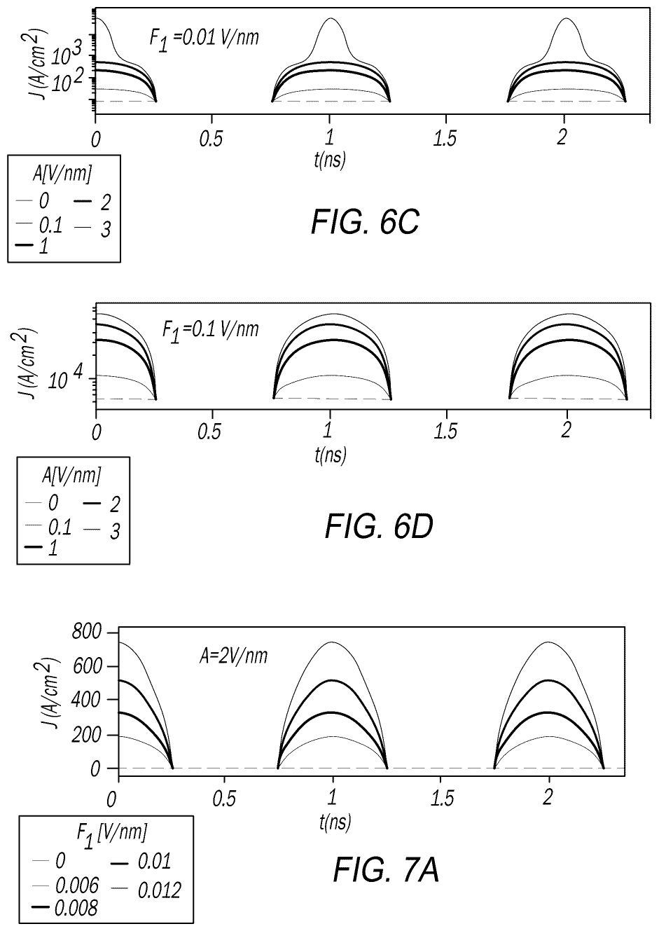

Electron emission under an RF field and a continuous laser field will now be discussed with regard to FIGS. 6A-D. Electron emission current density J varies with t under different combinations of RF field strength and laser field strength. The amplitude of the RF field A corresponding to the noted curves (bottom to top in each figure) is 0, 0.1, 1, 2, and 3 V/nm, respectively. Moreover, the frequency of the RF field is 1 GHz. In FIG. 6A, current density under RF only (F₁=0) is plotted, and the dotted black lines are plotted from the FN approximation, Eq. (3). The laser field has a wavelength of 200 nm and strength F₁=(b) 0.001, (c) 0.01, and (d) 0.1 V/nm.

FIGS. 6A-D show the periodic bunched emission current density J calculated from Eq. (2) during the positive RF half-cycles under various combinations of laser and RF field strength. The cathode is assumed to be gold, with nominal work function W₀=5.1 eV and Fermi energy ε_{F}=5.53 eV. The temperature is T=300 K. Unless prescribed otherwise, these are default cathode properties for the analysis herein. Also, the laser has a wavelength of 200 nm, and its heating effects are ignored due to the weak laser intensity used. RF field has a frequency of 1 GHz, with its negative half-cycles neglected in the calculation.

The RF field magnitudes A corresponding to the noted curves (bottom to top in each figure) are 0, 0.1, 1, 2, and 3 V/nm, respectively. In FIG. 6A, emission current density J is plotted under the RF field only with A=1, 2, and 3 V/nm (bottom to top) calculated from Eq. (2), which are almost identical to the current density calculated (black dotted line) from Fowler-Nordheim (FN) approximation equation,

$$J = α {aW}^{- 1} {{F}_{0}}^{2} exp ( - \frac{β {bW}^{\frac{3}{2}}}{{F}_{0}} ) , \qquad ( 3 )$$

where a≈2.46 965×10⁻²⁵ AJV⁻² and b≈1.06 515×10³ J^{-3/2} Vm⁻¹ are the first and second FN constants, and α=1 and β=1 are generalized correction factors. The emission current density for the cases under only laser fields of 0.001, 0.01, and 0.1 V/nm reads 0.5, 53, and 5282 A/cm², respectively, as shown at the bottom of FIGS. 6B-D, which are much larger than that of with RF field only in FIG. 6A. With the 10 times increase of laser field, the corresponding emission current density is increased by about 100 times without the RF field. As the laser field increases from 0.001 V/nm to 0.1 V/nm with the RF field, as shown in FIGS. 6B-D, the peak emission current density increases from 1 A/cm² to 10715 A/cm² for A=0.1 V/nm. A larger A increases the emission current density even further.

Thus, the presence of photons provides significant flexibility in controlling the emission current. More importantly, the shape of the temporal emission current density J varies in different combinations of the RF amplitude and laser field. From FIGS. 6A-D, when the RF field dominates the emission process (i.e., large RF field but small laser field), the shape of the temporal emission current density is in Gaussian profile. But when increasing the laser field, the current density profiles change towards a sinusoidal shape.

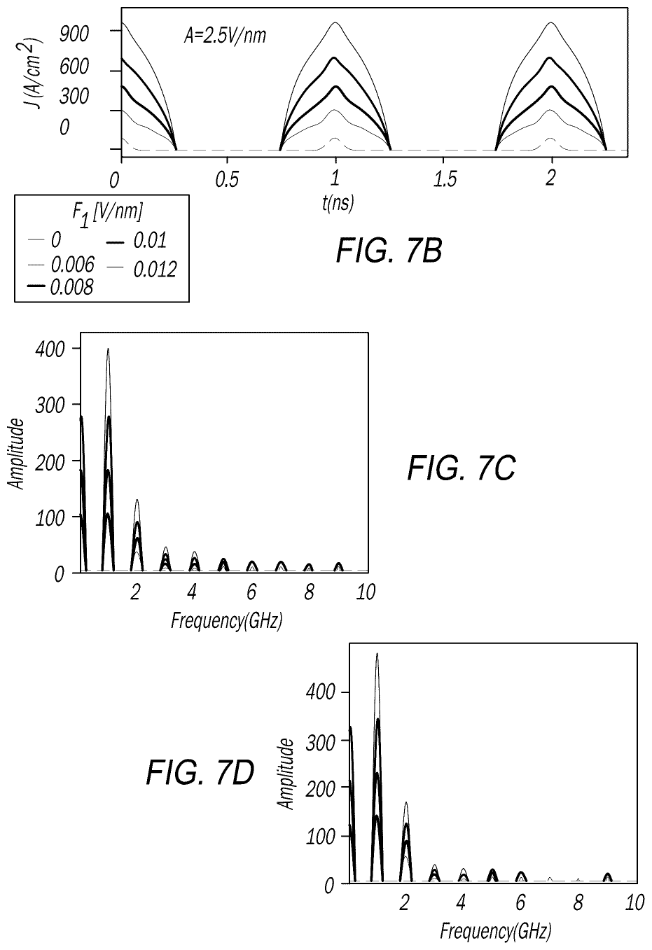

Referring now to FIGS. 7A and B, emission current density J varies with time t in 2.5 cycles under various laser fields with the RF amplitude A=2 and 2.5 V/nm, respectively. FIGS. 7C and D show an amplitude spectrum of the emission current density at the multiples of RF frequency (1 GHz) for corresponding FIGS. 7A and B. The laser wavelength is 200 nm.

The noted lines (bottom to top in each figure) correspond to F₁=0, 0.006, 0.008, 0.01, 0.012 V/nm. The corresponding optical intensities I [MW/cm²]=ε₀cF₁²/2=1.327×10⁵×(F₁ [V/nm])² are 0, 4.8, 8.5, 13.3, 19.1 MW/cm², where c is the speed of light in vacuum, for linearly polarized lasers. When A=2 V/nm, those curves can be fitted with a sinusoidal function of a magnitude of 740, 514, 329, 185, 0.18 A/cm² from top to bottom and a frequency of 1 GHz. Furthermore, as A increases, the shape of the emission current changes from an approximately sinusoidal shape to a Gaussian-like profile, similar to FIGS. 6A-D. Because of the high nonlinearity of photo-assisted field emission, increasing A produces a sharp peak in the middle, and the width of the peak becomes wider, as shown in FIG. 7B. It is also found that as A increases from 2 V/nm to 3 V/nm, the difference in emission current under different laser fields gets smaller. This is because the RF field is much larger than the laser field, and it plays the dominant role in modulating the emission current.

A frequency domain analysis of the emission current is done using the fast Fourier transform (“FFT”). The amplitude spectrum of emission current density at multiples of RF frequency (1 GHz) is shown in FIGS. 7C and D, corresponding to FIGS. 7A and B, respectively. The dominant frequency term is observed at 1 GHz, which is the same as the frequency of the RF field. For a given A, increasing the laser field tends to increase more on the fundamental frequency component in the emission current.

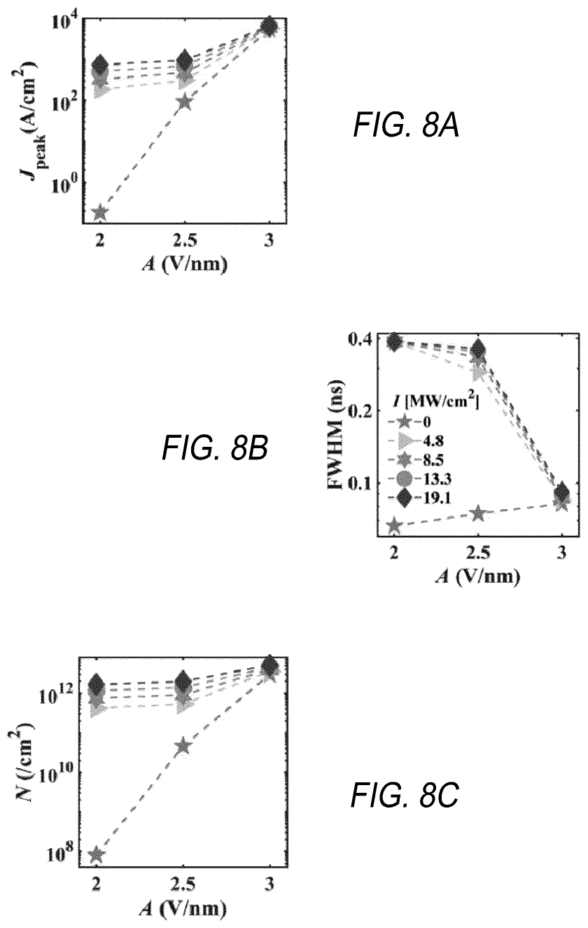

The effect of the RF field on the modulation of electron beams is provided in FIGS. 8A-C, with different laser fields 0, 0.006, 0.008, 0.01, 0.012 V/nm, corresponding to the intensity of I=0, 4.8, 8.5, 13.3, 19.1 MW/cm². FIG. 8A shows that the peak emission current density increases with the RF field. When A=3 V/nm, the peak emission current density remains almost unchanged for the given range of laser intensity due to the dominant direct tunneling under the RF field. FIG. 8B shows the full width at half maximum (FWHM) under different RF fields. When A=2 V/nm, there is a sharp increase of FWHM as I increases from 0 to 4.8 MW/cm². FWHM remains constant as I further increase. When A=2.5 V/nm, after the sharp increase of FWHM as I increases from 0 to 4.8 MW/cm², FWHM gradually increases as I further increases. When A=3 V/nm, FWHM almost keeps constant since RF field strength is much larger than the laser field and the modulation by the laser field becomes weak.

FIG. 8C shows the number of emitted electron flux per RF cycle, N, which is calculated by,

$$N = \frac{1}{e} {\int }_{0}^{2 π / {ω}_{0}} J ( t ) dt , \qquad ( 4 )$$

where J(t) is the temporal emission current density calculated from Eq. (2). It is interesting to find that N has similar trends as peak emission current density. This may indicate that for CW lasers, the laser intensity has a stronger influence on the emission current amplitude and a weaker influence on the modulation of beam width, especially when the RF field is much larger than the laser field strength.

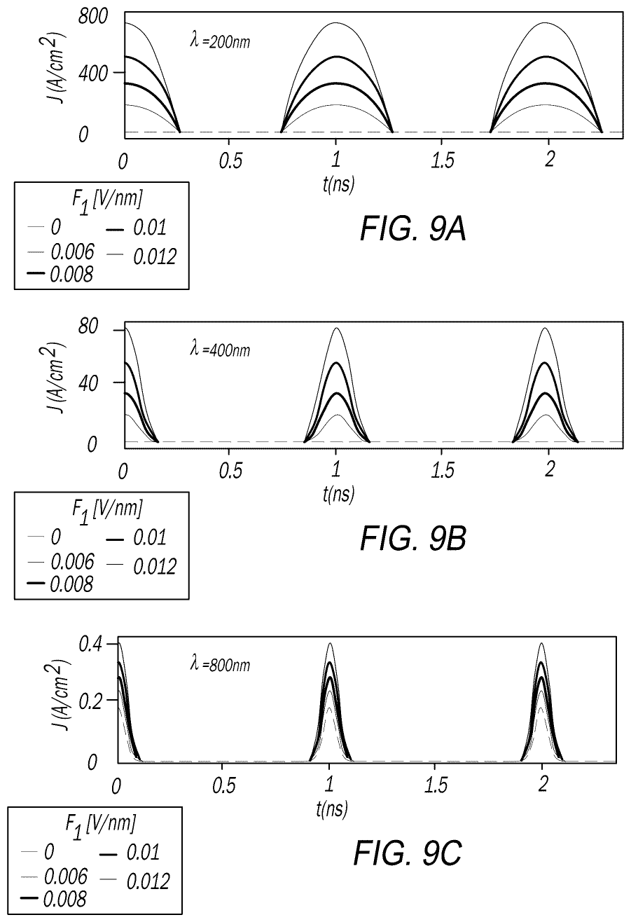

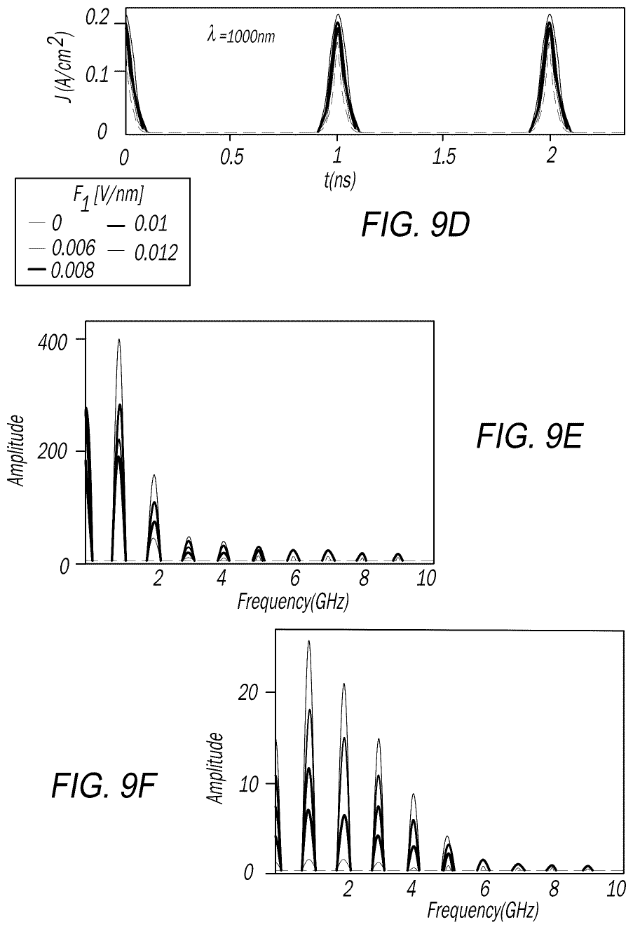

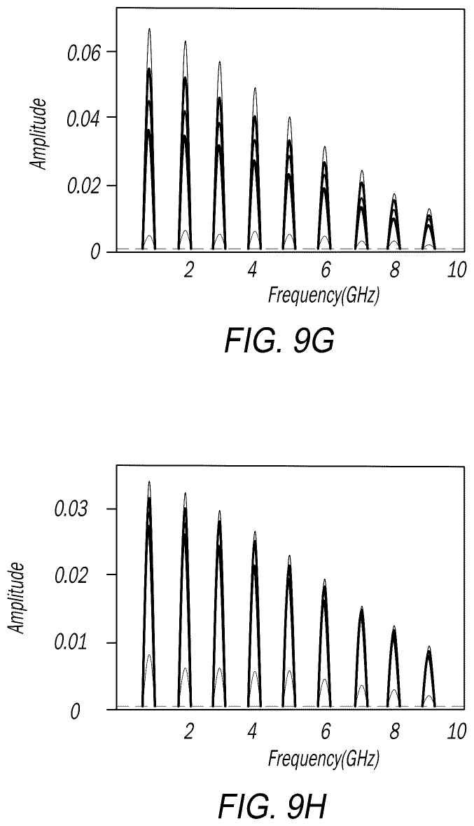

Reference should now be made to FIGS. 9A-H which shows the effect of laser wavelength on emission current density J. FIGS. 9A-D illustrates A=200, 400, 800, and 1000 nm, respectively. Moreover, FIGS. 9E-H depict amplitude spectra of the emission current density at multiples of RF frequency, corresponding to FIGS. 9A-D respectively. RF field amplitude A=2 V/nm.

For fixed laser and RF field strength, emission current density decreases rapidly as laser wavelength increases. This is because of the lower quantum efficiency for longer laser wavelengths. When F₁ increases from 0.006 to 0.012 V/nm, the peak emission current density increases from 185 to 740 A/cm² for A=200 nm and from 0.20 to 0.23 A/cm² for λ=1000 nm. A shorter wavelength laser has stronger effects on the modulation of the emission current. It is also observed that as the laser wavelength increases, the peak width decreases. FIGS. 9E-H show the amplitude spectra of emission current density at multiples of RF frequency (1 GHz) using FFT, corresponding to FIGS. 9A-D, respectively. Additionally, as laser wavelength increases, there appears more higher-harmonic contents in the density-modulated electron beam.

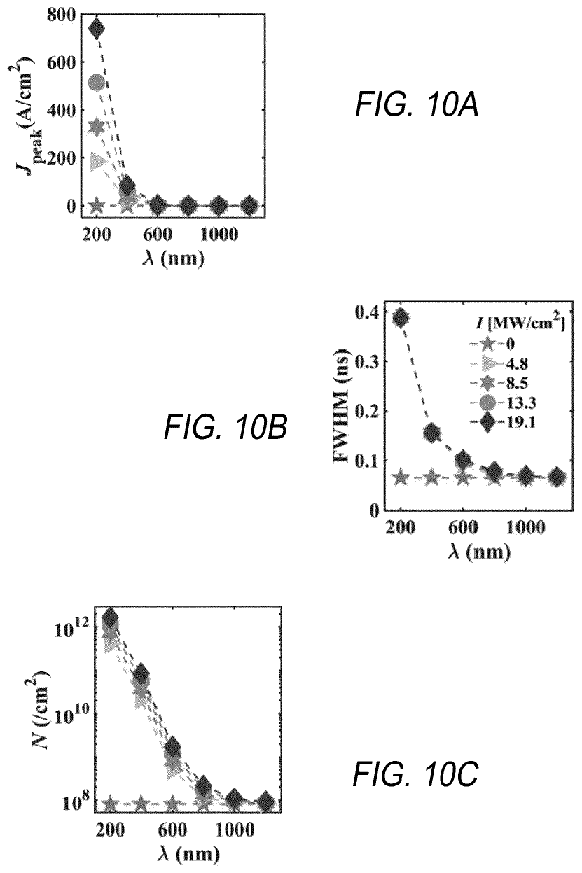

The effect of laser wavelength on the modulation of emission current (i.e., peak emission current density, FWHM, and the number of emission electrons per RF cycle) is shown in FIG. 10A-C. FIG. 10A shows the peak emission current density as a function of the laser wavelength range from 200 to 1200 nm with an interval of 200. It is apparent the peak emission current density decreases quickly when the laser wavelength A changes from 200 to 600 nm and then levels off for longer wavelengths, where the peak current density is also insensitive to the laser intensity. FIG. 10B shows the FWHM of the current pulse decreases rapidly with A change from 200 to 1200 nm. Also, increasing laser intensities from 4.8 to 19.1 MW/cm² has little influence on the FWHM of the current pulse with fixed λ. FIG. 10C shows the number of emitted electron fluxes per RF cycle, N, in different wavelengths. When the laser intensity is fixed at 19.1 MW/cm², the number of emitted electrons is 1.6×10¹², 8.4×10¹⁰, 1.7×10⁹, 2.1×10⁸, 1.1×10⁸, 9.0×10⁷ in wavelength being 200, 400, 600, 800, 1000, 1200 nm, respectively. It is noticeable that N shows similar trends as peak emission current density. This indicates again that, for CW lasers, the laser intensity has a stronger influence on the emission current amplitude and a smaller influence on the beam width. In FIG. 10C, the number of emitted electrons in a half RF cycle is depicted as a function of laser wavelength under various laser intensities. RF field amplitude A=2 V/nm and the corresponding laser field strength is F₁=0, 0.006, 0.008, 0.01, 0.012 V/nm for the intensity of I=0, 4.8, 8.5, 13.3, 19.1 MW/cm².

Electron emission under an RF field and a pulsed laser field is hereinafter set forth. FIG. 11A illustrates an emission current density temporal profile under a pulsed laser of full-width-half-maximum τₚ=0.05 ns. FIG. 11B shows an amplitude spectra of the emission current density at multiples of RF frequency, corresponding to FIG. 11A. The laser wavelength is 200 nm and A=2.5 V/nm. The corresponding laser intensity is I=19.1, 13.3, 8.5, 4.8, 0 MW/cm² for F₁=0.012, 0.01, 0.008, 0.006, 0 V/nm.

For simplicity, it is assumed that the peak of the laser field aligns with the peak of the RF field in all the pulsed laser calculations. As the laser pulse length decreases, the emitted electron beam width decreases, while the peak emission current density stays the same for a fixed laser field. For a given RF field amplitude A and laser pulse duration τₚ, peak emission current density increases, but beam width decreases when F₁ increases. Compared to the RF field only case (black dotted lines), the emission current density induced by combined RF and laser fields is increased by more than 10 times.

In comparison with the emission current density under a CW laser field (FIGS. 7A and B), the width of the electron beam becomes narrower and can be controlled by the laser pulse duration. FIG. 11B shows the FFT amplitude spectra at multiples of RF frequency accordingly. For each τₚ, the amplitude of the spectra decreases with frequency. As τₚ decreases, the reduction of higher harmonics becomes slower. Compared with the CW laser field (FIGS. 7C, 7D and 9E-H), pulsed laser-induced electron emission has higher-harmonic terms.

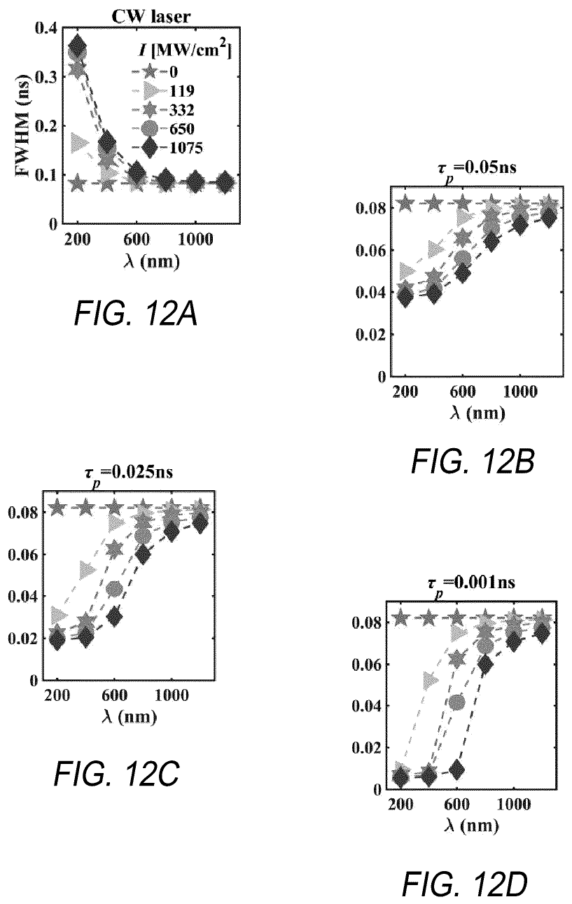

FIGS. 12A-D depict full width at half maximum (“FWHM”) of the emission current density as a function of laser wavelength under various laser intensities. More particularly, a continuous-wave laser field in FIG. 12A; a pulsed laser of duration τₚ=0.05 ns in FIG. 12B; a pulsed laser of duration τₚ=0.025 ns in FIG. 12C; and a pulsed laser of duration τₚ=0.001 ns in FIG. 12D. Here, RF field amplitude A=3 V/nm. The corresponding laser intensity is I=0, 119, 332, 650, 1075 MW/cm² for F₁=0, 0.03, 0.05, 0.07, 0.09 V/nm.

For comparison, the width of the emission current density for a CW laser with A=3 V/nm is shown in FIG. 12A, which has a similar trend as in FIG. 10B. For a pulsed laser, the pulse width of the emission current density increases with laser wavelength for a given laser intensity, while it decreases with the laser intensity for a given laser wavelength. The emitted current pulse width is more sensitive to laser intensity for shorter laser wavelengths.

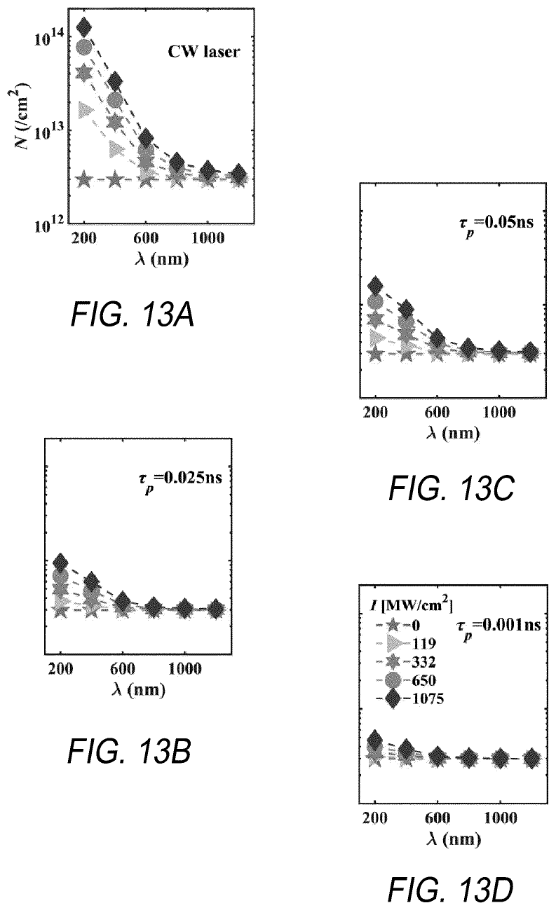

Reference is made to FIGS. 13A-D. The number density of emitted electrons per RF cycle as a function of laser intensity under different wavelengths for a continuous-wave laser field in FIG. 13A; a pulsed laser of duration τₚ=0.05 ns in FIG. 13B; a pulsed laser of duration τₚ=0.025 ns in FIG. 13C; and a pulsed laser of duration τₚ=0.001 ns in FIG. 13D. Here, RF field amplitude A=3 V/nm. The number density of emitted electrons per RF cycle N is set forth under laser fields of various duration. It can be found that N decreases when the wavelength increases or laser intensity decreases. As the pulsed laser duration decreases, N becomes less sensitive to laser intensity and wavelength.

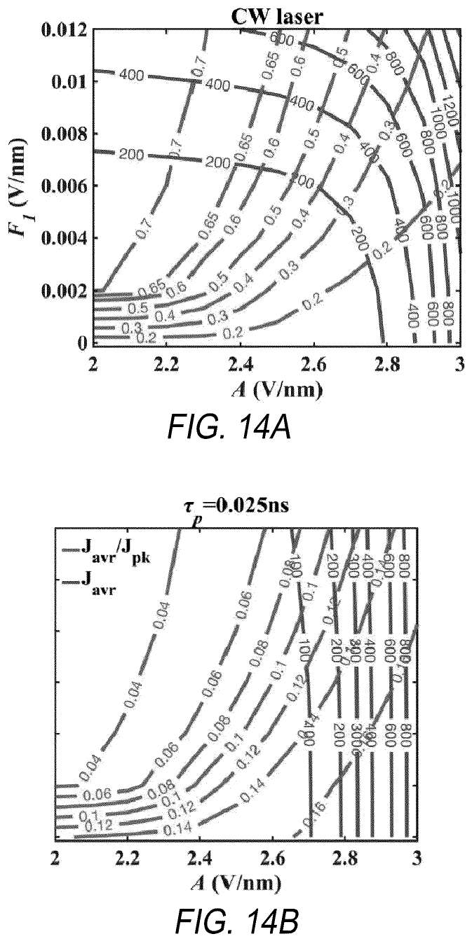

Finally, FIGS. 14A and B show contours of constant average current density Jₐᵥᵣ and the ratio of average over the peak of current density Jₐᵥᵣ/Jₚₖ calculated using the quantum electron emission model in Eq. (2), where FIG. 14A is for a CW laser, and FIG. 14B is for a pulsed laser with duration τₚ=0.025 ns. It shows that both density Jₐᵥᵣ and Jₐᵥᵣ/Jₚₖ can be adjusted over a wide range of values by controlling RF amplitude, laser field, and laser pulse duration. It also shows significantly increased flexibility to achieve density modulation during electron emission over a wide range of parameter space by using optical photons, as compared to voltage-controlled field emission. The Jₐᵥᵣ/Jₚₖ is as small as 0.04 can be achieved using pulsed lasers as can be observed in FIG. 14B, which is an order of magnitude smaller than the typical value of Jₐᵥᵣ/Jₚₖ>0.3 from voltage-controlled field emission. An average current density Jₐᵥᵣ [A/cm²] and the ratio of average over the peak of current density Jₐᵥᵣ/Jₚₖ are in various RF amplitudes and laser fields with a 200 nm wavelength, using a CW laser in FIG. 14A, and using a pulsed laser of duration τₚ=0.025 ns in FIG. 14B.

In summary, the present apparatus and method are well suited to use various pulse shapes of pre-bunched electron beams emitted from an RF cold cathode under different combinations of RF field and optical field (continuous-wave or pulsed). The profile of the produced emission current can be modulated by varying RF field (amplitude and frequency) and optical field (laser wavelength, laser intensity, pulse length). The emission current pulse amplitude, beam width (i.e., FWHM of the current pulse), and electron numbers per pulse, as well as the harmonic spectrum, are analyzed herein with various combinations of RF and optical fields. The photo-assisted field emission under the combination of RF field and optical field is significantly larger than electron emission due to either the RF field or optical field alone. For CW photon sources in the UV to optical range (i.e., 200 nm-800 nm), increasing the optical intensity under an RF bias tends to change the shape of the current emission pulse from a Gaussian-like profile towards a sinusoidal-like profile, thus offering great flexibility to control the harmonic contents in electron beam current emission.

Furthermore, pulsed photon sources together with an RF field can produce sharp, high-current electron bunches with pulse duration comparable with or even less than that of the optical pulse. The preceding contour map demonstrates the achievement of a wide range of average current density and density modulation depth (in terms of the ratio of average-to-peak current density), by controlling the RF field and laser field (either CW or pulsed). This allows, for example, direct density modulation during electron current emission using optical photons, which may be utilized to enhance the operational efficiency of free-electron beam-based electronics, such as TWTs or particle accelerators.

While various features of the present invention have been disclosed, it should be appreciated that other variations may be employed. For example, different light sources may be used instead of a CW or pulsed femtosecond laser, such as a star. For example, alternate shapes, configurations and positions can be employed for the cold cathode and its tips, although various advantages of the present system may not be realized. As another example, the preferred electrical circuits and vacuum chamber wall surfaces may have different shape and components than those illustrated, but certain benefits may not be obtained. Variations are not to be regarded as a departure from the present disclosure, and all such modifications are intended to be included within the scope and spirit of the present invention.

The invention claimed is:

1. A method of using an electron beam, the method comprising:
(a) sending a radio frequency field to an electron beam cathode;
(b) emitting the electron beam from tapered tips of the electron beam cathode, within a vacuum chamber;
(c) contacting photons with at least one of the cathode and the electron beam, within the vacuum chamber; and
(d) creating electron bunches within the vacuum chamber.

2. The method of claim 1, further comprising:
emitting the photons from a laser; and
the electron beam cathode being a cold cathode.

3. The method of claim 2, further comprising controlling operation of a radio frequency source, which sends the radio frequency field, and the laser, with a programmable controller.

4. The method of claim 2, wherein the laser is a continuous wave laser.

5. The method of claim 2, wherein the laser emits pulses of the photons into the vacuum chamber.

6. The method of claim 1, further comprising:
causing the electron beam cathode to be optically gated;
densifying the electron bunches at a repetition rate of a microwave frequency within the vacuum chamber; and
synchronizing the electron bunches and the microwave frequency via the radio frequency field and a laser at a predetermined level so that high-current electron emission occurs only when the laser is triggered.

7. The method of claim 1, further comprising controlling a bunch length of electrons by tuning a trigger level voltage of a laser, the laser emitting the photons.

8. The method of claim 1, further comprising causing an electron current pulse to have a substantially sinusoidal shape, due to the photons being 200 nm-800 nm under a radio frequency bias, which allows frequency component control of current emissions from the electron beam.

9. The method of claim 1, further comprising directly modulating density of the electron bunches during electron current emissions, by controlling a characteristic of the photons.

10. The method of claim 1, further comprising creating the electron bunches with sharp and high-current characteristics, due to combining of the photons, which are pulsed, and the radio frequency field.

11. The method of claim 1, further comprising selectively exciting individual ones of the tips of the electron beam cathode using optical gating, simultaneously causing multiple electron beams with separate modulations by various combinations of emission of the radio frequency field, emission of the photons and/or thermionic emission.

12. The method of claim 1, further comprising using an output radio frequency signal leaving the vacuum chamber as part of an outer space satellite communication signal, and the photons being received from a star.

13. A method of using an electron beam, the method comprising:
(a) emitting electron current from a radio frequency cold cathode; and
(b) using optical excitation to directly modulate density of electron bunches created during the electron current emissions.

14. The method of claim 13, wherein:
the emitting the electron current is from multiple tapered tips of the cathode, within a vacuum chamber;
the using optical excitation includes contacting photons with at least one of the cathode and the electron beam, within the vacuum chamber; and
further comprising creating the electron bunches with sharp and high-current characteristics, due to combining of the photons and a radio frequency field.

15. The method of claim 13, further comprising controlling operation of a radio frequency source and a laser, with a programmable controller.

16. The method of claim 13, further comprising using a continuous wave laser to cause the optical excitation by emitting photons through a window in a vacuum chamber housing.

17. The method of claim 13, further comprising using a laser to cause the optical excitation by emitting pulses of photons through a window in a vacuum chamber housing.

18. The method of claim 13, further comprising:
causing the cathode to be optically gated;
densifying the electron bunches at a repetition rate of a microwave frequency; and
synchronizing the electron bunches and the microwave frequency with a radio frequency field and a laser at a predetermined level so that high-current electron emission occurs only when the laser is triggered.

19. The method of claim 13, further comprising controlling a bunch length of electrons by tuning a trigger level voltage of a laser.

20. The method of claim 13, further comprising receiving photons from a star into a vacuum chamber to cause the optical excitation therein.

21. A method of using an electron beam, the method comprising:
(a) sending a radio frequency field to a cold cathode;
(b) emitting electron bunches from multiple tapered tips of the cold cathode, within a vacuum chamber;
(c) emitting photons from a laser, into the vacuum chamber; and
(d) directly modulating density of the electron bunches with the photons.

22. The method of claim 21, further comprising controlling operation of a radio frequency source and the laser, with a programmable controller.

23. The method of claim 21, further comprising:
causing the cathode to be optically gated;
densifying the electron bunches at a repetition rate of a microwave frequency; and
synchronizing the electron bunches and the microwave frequency with the radio frequency field and the laser at a predetermined level so that high-current electron emission occurs only when the laser is triggered.

24. The method of claim 21, further comprising controlling a bunch length of electrons by tuning a trigger level voltage of the laser.

25. The method of claim 21, further comprising creating the electron bunches with sharp and high-current characteristics, due to combining of the photons, which are pulsed, and the radio frequency field.

26. The method of claim 21, further comprising using software instructions, stored in nontransient memory, to selectively excite individual ones of the tips of the cathode and cause different electron density areas within an electron bunch.
